(19) United States
(12) Patent Application Publication
(10) Pub. No.: US 2013/0222985 A1
(43) Pub. Date: Aug. 29, 2013

(54) ELECTRONIC CONTROL APPARATUS

(71) Applicant: Denso Corporation, (US)

(72) Inventor: Hiroyuki IBARAKI, Kariya-city (JP)

(73) Assignee: DENSO CORPORATION, Kariya-city (JP)

(21) Appl. No.: 13/772,940

(22) Filed: Feb. 21, 2013

(30) Foreign Application Priority Data
Feb. 29, 2012 (JP) 2012-43247

(51) Int. Cl. H05K 7/00

(52) U.S. Cl. CPC H05K 7/00
USPC 361/679.01

(57) ABSTRACT

An electronic control apparatus, which transmits and receives an electrical signal via a wire, includes a control unit, a housing in which the control unit is arranged, a connector having a first end and a second end, a fixing member, and a supportive member. The first end of the connector is electrically coupled to the control unit, and the second end of the connector is electrically coupled to the wire. The fixing member is arranged on the wire. The supportive member, which supports the wire, is fixed to the housing, and the wire is fixed to the supportive member via the fixing member.

### CROSS REFERENCE TO RELATED APPLICATION

This application is based on Japanese Patent Application No. 2012-043247 filed on Feb. 29, 2012, the disclosure of which is incorporated herein by reference.

### TECHNICAL FIELD

The present disclosure relates to an electronic control apparatus.

### BACKGROUND

Conventionally, an electronic control apparatus for a vehicle includes a connector for connecting with a communication cable. For example, an electronic control apparatus disclosed in JP 2011-167032 A includes a first connector and a second connector, which are separate from one another. The second connector is detachable from the first connector, and the first connector is coupled to a control target via the communication cable.

In the electronic control apparatus disclosed in JP 2011-167032 A, the first connector and the second connector are not fixed to vibrate in the same phase during a vibration of a running vehicle to which the electronic control apparatus is equipped. Thus, the vibration of the running vehicle may lead to a fretting corrosion between terminals of the first connector and terminals of the second connector. The fretting corrosion between the terminals of the first connector and the terminals of the second connector degrade a reliability of an electrical coupling between the first connector and the second connector.

### SUMMARY

In view of the foregoing difficulties, it is an object of the present disclosure to provide an electronic control apparatus in which a reliability of an electrical coupling between electrically coupling parts of connectors is improved by restricting a fretting corrosion between the electrically coupling parts of the connectors.

According to an aspect of the present disclosure, an electronic control apparatus, which transmits and receives an electrical signal via a wire, includes a control unit, a housing in which the control unit is arranged, a connector having a first end and a second end, a fixing member, and a supportive member. The first end of the connector is electrically coupled to the control unit, and the second end of the connector is electrically coupled to the wire. The fixing member is arranged on the wire. The supportive member, which supports the wire, is fixed to the housing, and the wire is fixed to the supportive member via the fixing member.

In the above apparatus, a reliability of an electrical coupling between electrically coupling parts of connectors is improved by restricting a fretting corrosion between the electrically coupling parts of the connectors.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a diagram showing an electronic control apparatus according to an embodiment of the present disclosure;

FIG. 2 is a diagram showing a plan view of the electronic control apparatus viewed in direction II in FIG. 1;

FIG. 3 is a diagram showing a plan view of the electronic control apparatus viewed in direction III in FIG. 2;

FIG. 4 is a diagram showing a plan view of the electronic control apparatus viewed in direction IV in FIG. 3; and

FIG. 5 is a diagram showing a cross sectional view of the electronic control apparatus viewed in line V-V in FIG. 4.

### DETAILED DESCRIPTION

The following will describe an electronic control apparatus 1 according to an embodiment of the present disclosure with reference to the drawings.

### First Embodiment

The electronic control apparatus 1 according to the present embodiment is used in an electric power steering apparatus or an electric power steering system (EPS). The electronic control apparatus 1 controls a motor 94 based on a torque amount of a steering wheel 91 of a vehicle and a rotation angle signal of the motor 94 in order to generate a steering power assist.

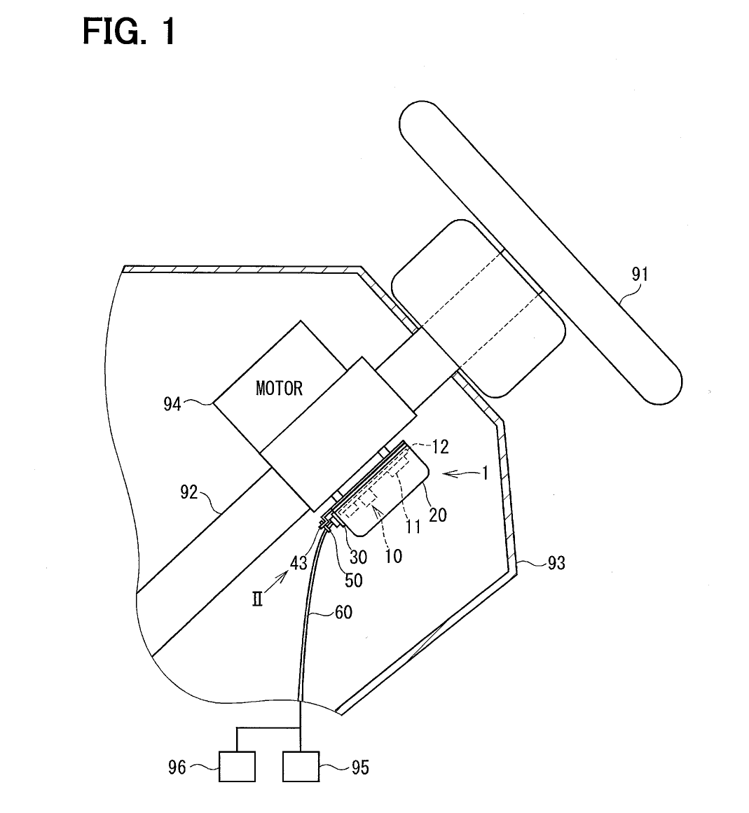

The electronic control apparatus 1 according to the present embodiment will be described with reference to FIG. 1 to FIG. 4. As shown in FIG. 1, the electronic control apparatus 1 is arranged inside of a dashboard 93 of the vehicle. Specifically, the electronic control apparatus 1 is arranged around a shaft 92, which is connected to the steering wheel 91.

The electronic control apparatus 1 includes a control unit 10, a housing 20, a connector 30, a bracket 40, and a binding member 50. The binding member 50 is provided as an example of a fixing member.

The control unit 10 includes electronic components 11 and a substrate on which the electronic components 11 are arranged. The electronic components 11 include a metal oxide semiconductor (MOS), an aluminum electrolytic capacitor, a coil, a relay, a shunt resistor and the like. The control unit 10 detects a torque signal of the steering wheel 91 and the rotation signal of the motor 94, which are necessary to control the EPS. Further, the control unit 10 determines an amount of the steering power assist based on a rotation signal of an engine, a speed signal of the vehicle, a battery voltage, an electric load signal and the like.

The housing 20 has an approximate rectangular parallelopiped shape, and includes a cap member 21 and a receiving member 22. The cap member 21 is made of metal, such as iron, and has a container shape. The receiving member 22 is made of metal, such as aluminum. A housing space 23 is defined between the cap member 21 and the receiving member 22 by covering an opening of the cap member 21 with the receiving member 22. The control unit 10, which is fixed to the receiving member 22, is arranged in the housing space 23.

The connector 30 has a first end 301, which is electrically coupled to the control unit 10, and a second end 302. The first end 301 is arranged inside of the housing 20, and the second end 302 end is arranged outside of the housing 20. More specifically, the second end 302 is exposed from the cap member 21.

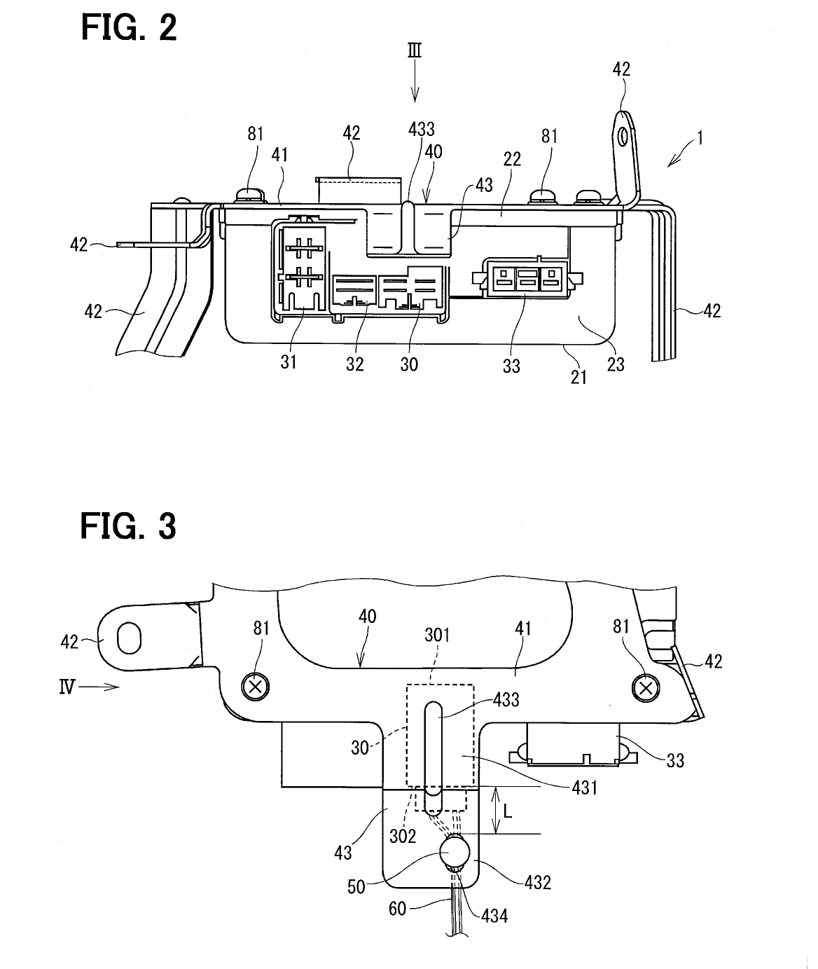

As shown in FIG. 2, other connectors 31, 32, 33 are electrically coupled to the control unit 10. Other connectors 31, 32, 33 are referred to as non-subject connectors in order to distinguish the connector 30 from other connectors 31, 32, 33. As shown in FIG. 1, the connector 30 is electrically coupled to one or more wires 60 via a wire connector 61. The wires 60 transmit signals detected from a torque sensor 95 and a rotation angle sensor 96. The non-subject connector 31 is electrically coupled to a wire, which supplies electric power to the control unit 10. The non-subject connector 32 is electrically coupled to a communication cable which performs a communication based on a controlled area network (CAN). The communication based on the CAN is also referred to as a CAN communication. The non-subject connector 33 is electrically coupled to a communication cable which transmits a control signal for the motor 94.

The bracket 40 is made of metal, such as iron, and includes a body 41, a fixing arm 42, and a supportive arm 43. The supportive arm 43 is provided as an example of a supportive member. The body 41 has an approximate plate shape, and is fixed to the receiving member 22 via screws 81. The fixing arm 42 fixes the bracket 40 to a body of the vehicle via screws (not shown). Thus, the bracket 40 can support the housing 20 that is fixed to the body 41 of the bracket 40.

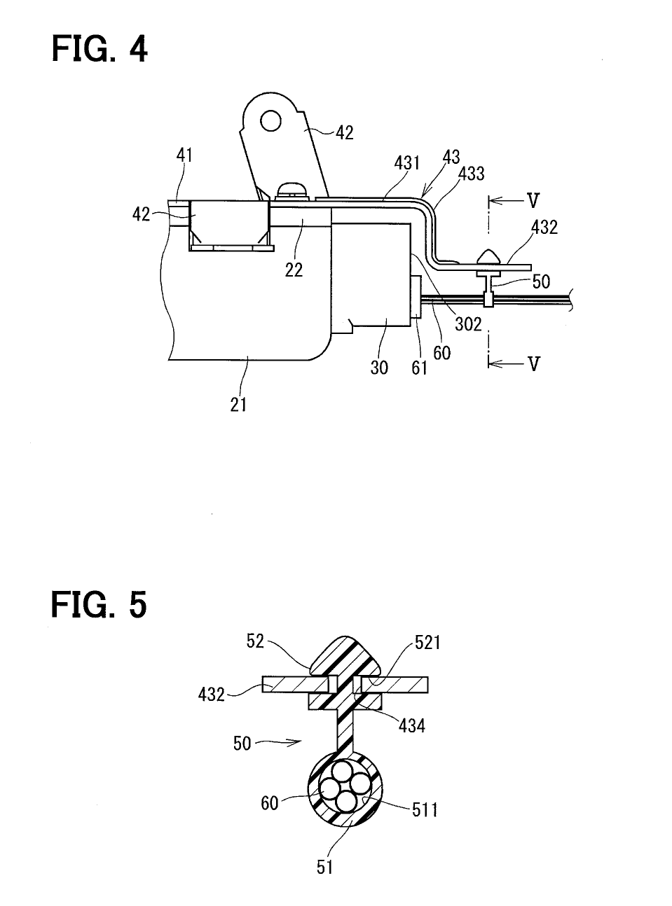

As shown in FIG. 3 and FIG. 4, the supportive arm 43 has a plate shape, and extends along a longitudinal line of the connector 30. Herein, the longitudinal line of the connector 30 is defined as a line which passes through the first end 301 and the second end 302 of the connector 30. Further, in a direction from the first end 301 to the second end 302 of the connector 30, the supportive arm 43 extends past the second end 302 of the connector 30. Specifically, an end of the supportive member extends past the second end 302 of the connector 30. The supportive arm 43 may have a crank-shape on a plane perpendicular to a surface on which the body 41 of the bracket 40 is placed. Hereinafter, the surface on which the body 41 of the bracket 40 is placed is also referred to as a reference surface. The supportive arm 43 includes a junction section 431, a pedestal section 432, and a reinforcement rib 433. In the present embodiment, the supportive arm 43 is arranged corresponding to a connecting part of the connector 30.

As shown in FIG. 4, the junction section 431 is connected to the body 41 of the bracket 40 and has an L-shape on the plane perpendicular to the reference surface. The pedestal section 432 is arranged on an opposite side of the junction section 431 from the body 41. The pedestal section 432 defines a through hole 434. As shown in FIG. 3, the through hole 434 is defined such that a predetermined end of the through hole 434 is apart from the second end 302 of the connector 30 by a predetermined distance L in the longitudinal line of the connector 30. The predetermined end of the through hole 434 is an end which is adjacent to the control unit 10. The reinforcement rib 433 is protruded from a surface of the supportive arm 43 in a direction perpendicular to the surface of the supportive arm 43. Further, the reinforcement rib 433 is arranged on a longitudinal centerline of the supportive arm 43. That is, the reinforcement rib 433 extends along a longitudinal direction of the supportive arm 43.

The binding member 50 is made of, for example, resin material. As shown in FIG. 5, the binding member 50 includes a binding ring 51 and a stopper 52. The binding ring 51 defines a binding hole 511 through which the wires 60 pass. The stopper 52 has an H-shaped cross section on the plane perpendicular to the reference surface as shown in FIG. 5. Specifically, a groove 521 is defined around the stopper 52 so that the stopper 52 engages with the pedestal section 432. The binding member 50 binds the wires 60, and further, fixes the wires 60 to the supportive arm 43 by an engagement between the stopper 52 and the pedestal section 432 via the through hole 434. Further, the through hole 434 is apart from the second end 302 of the connector 30 by the predetermined distance L. Thus, the binding member 50 fixes the wires 60 to the supportive arm 43 at a point, which is apart from the second end 302 of the connector 30 by the predetermined distance L.

As described above, the wires 60 that are electrically coupled to the connector 30 are fixed to the supportive arm 43 via the binding member 50. Further, the supportive arm 43 is fixed to the housing 20. Thus, the wires 60 between the binding member 50 and the connector 30 vibrate in the same phase with the supportive arm 43 and the housing 20. Accordingly, the wire connector 61 and the connector 30 vibrate in the same phase. Thus, a fretting corrosion between electrically coupling parts of the wires 60, such as terminals, and electrically coupling parts of the connector 30, such as terminals, is restricted. Accordingly, an attrition between the electrically coupling parts of the wires 60 and the electrically coupling parts of the connector 30 is restricted. Further, the wires 60 are fixed to the housing 20 via the supportive member 43. Thus, a reliability of an electrical coupling between the wires 60 and the connector 30 is increased.

JP 3292281 B2 discloses a structure in which the fretting corrosion between coupling parts of connectors are restricted. In JP 3292281 B2, a connector includes a pair of elastic arms, which engage with a through hole defined by an instrument panel. The other connector includes a pair of elastic arms, which contacts with a fixed wall in order to bias the other connector against the fixed wall. With this configuration, a fretting corrosion between terminals of the two connectors is restricted. Accordingly, a reliability of electrical coupling between the two connectors is improved. The configuration disclosed in JP 3292281 B2 is made for purpose. Thus, the configuration has less versatility. The above-described configuration in the present embodiment may be applied to, without limitation, a connector other than the connecter of the electronic control apparatus disclosed in JP 3292281 B2.

In the present embodiment, the supportive arm 43 extends toward a direction, which is opposite to a direction from the supportive arm 43 to the control unit 10. Thus, when fixing the wires 60 to the supportive arm 43, there is no need to bend the wires 60 at a position near the connector 30. Thus, compared with a structure in which the wires 60 are bent at the position near the connector 30, a disconnection of the wires 60 is restricted.

In the present embodiment, the reinforcement rib 433 of the supportive arm 43 is protruded from the surface of the supportive arm 43 in the direction perpendicular to the surface of the supportive arm 43. Further, the reinforcement rib 433 extends along the longitudinal direction of the supportive arm 43. Thus, a vibration of the supportive arm 43 is restricted and the attrition between the electrically coupling parts of the wires 60 and the connector 30 is restricted.

In the present embodiment, the wires 60 are fixed to the supportive member by the binding member 50, which has the binding ring 51 and the stopper 52. Thus, the wires 60 can be bound by the binding member 50 with ease.

In the present embodiment, the wires 60 are fixed to the supportive arm 43 at the point, which is apart from the second end 302 of the connector 30 by the predetermined distance L. Thus, the vibration of the wires 60 is restricted.

### Other Embodiments

The foregoing embodiment describes a case in which the electronic control apparatus 1 is applied to the electric power steering apparatus or the electric power steering system. Further, the electronic control apparatus 1 may be applied to other apparatuses or systems.

In the foregoing embodiment, the binding member 50 is provided as an example of the fixing member. Further, other commercially available binding members may be used as the fixing member.

In the foregoing embodiment, the binding member 50, which functions as the fixing member, is fixed to the supportive arm 43 by the stopper 52. Further, the binding member 50 may be fixed to the supportive arm 43 by other fixing members, such as an adhesive tape and adhesive material.

In the foregoing embodiment, the wires 60, which transmit signals detected by the torque sensor 95 and the rotation angle sensor 96, are fixed to the supportive arm 43. Further, at least one of other wires, for example, a wire supplying the electric power to the control unit 10, a wire performing the CAN communication, and a wire transmitting the control signal of the motor 94 may be fixed to the supportive arm 43.

In the foregoing embodiment, the bracket 40, which is fixed to the receiving member 22, includes the supportive arm 43 as the supportive member. Further, the receiving member 22 or the cap member 21 may include the supportive arm 43 other than the bracket 40.

While only the selected exemplary embodiments have been chosen to illustrate the present disclosure, it will be apparent to those skilled in the art from this disclosure that various changes and modifications can be made therein without departing from the scope of the disclosure as defined in the appended claims. Furthermore, the foregoing description of the exemplary embodiments according to the present disclosure is provided for illustration only, and not for the purpose of limiting the disclosure as defined by the appended claims and their equivalents.

What is claimed is:

1. An electronic control apparatus, which transmits and receives an electrical signal via a wire, comprising:
a control unit;
a housing in which the control unit is arranged;
a connector having a first end and a second end, the first end electrically coupling to the control unit and the second end electrically coupling to the wire;
a fixing member arranged on the wire; and
a supportive member for supporting the wire, the supportive member being fixed to the housing and the wire being fixed to the supportive member via the fixing member.

2. The electronic control apparatus according to claim 1,
wherein the supportive member extends past the second end of the connector.

3. The electronic control apparatus according to claim 1,
wherein the supportive member has a plate shape,
wherein the supportive member includes a reinforcement rib, which is protruded from a surface of the supportive member in a direction perpendicular to the surface of the supportive member, and
wherein the reinforcement rib extends along a longitudinal direction of the supportive member.

4. The electronic control apparatus according to claim 1,
wherein the fixing member is a binding member.

5. The electronic control apparatus according to claim 1,
wherein the fixing member fixes the wire to the supportive member at a position, which is apart from the second end of the connector by a predetermined distance.

6. The electronic control apparatus according to claim 5,
wherein the binding member includes a binding ring and a stopper,
wherein the wire passes through the binding ring, and
wherein the stopper engages with the supportive member in order to fix the wire to the supportive member.

7. The electronic control apparatus according to claim 1,
wherein the connector is arranged such that the first end is arranged inside of the housing and the second end is arranged outside of the housing.
